(19) United States
(12) Patent Application Publication
(10) Pub. No.: US 2020/0091840 A1
(43) Pub. Date: Mar. 19, 2020

(54) GRAPHITE/GRAPHENE-THERMOELECTRIC GENERATOR

(71) Applicant: Amen Dhyllon, Wynnewood, PA (US)

(72) Inventor: Amen Dhyllon, Wynnewood, PA (US)

(73) Assignee: Serendipity Technologies LLC, Wynnewood, PA (US)

(21) Appl. No.: 16/132,590

(22) Filed: Sep. 17, 2018

(51) Int. Cl. H02N 11/00; H01L 35/30; H01L 35/32

(52) U.S. Cl. CPC H02N 11/008; H01L 35/30; C01B 32/158; H02N 11/002; H01L 35/32

(57) ABSTRACT

The present invention relates to a device and system for energy generation comprising (1) a thermoelectric generator, (2) a low-power solid-state carbon heating element, and (3) a coolant element. Once the capital cost is discounted, this invention can provide unlimited amounts of essentially “free” electricity using a and maintenance-free system.

### RELATIONSHIP TO OTHER APPLICATIONS

None

### FIELD OF THE INVENTION

The present invention relates to a thermoelectric generator using a graphite/graphine element to produce heat.

### BACKGROUND OF THE INVENTION

Thomas Seebeck, in 1821, discovered that a thermal gradient formed between two dissimilar conductors can produce electricity. A temperature gradient in a conducting material results in heat flow; this results in the diffusion of charge carriers. The flow of charge carriers between the hot and cold regions in turn creates a voltage difference electromotive force −EMF). In 1834, Jean Peltier discovered the reverse effect, that running an electric current through the junction of two dissimilar conductors could create heating or cooling.

A thermoelectric system generates power by virtue of a heat gradient. The bigger the gradient the greater the EMF generated. Heat exchangers are often used on both sides of the modules to supply this heating and cooling.

There are many challenges in designing a reliable TEG system that operates at high temperatures. Achieving high efficiency in the system requires extensive engineering design in order to balance between the heat flow through the modules and maximizing the temperature gradient across them. To do this, designing heat exchanger technologies in the system is one of the most important aspects of TEG engineering. In addition, the system requires minimization of thermal losses due to the interfaces between materials at several places. Another challenging constraint is avoiding large pressure drops between the heating and cooling sources.

TE modules produce DC electric power which can be passed through an inverter to produce AC power.

A thermoelectric generator (TEG), also called a Seebeck generator, is a solid-state device that converts heat flux (temperature differences) directly into electrical energy through a phenomenon called the Seebeck effect (a form of thermoelectric effect). Thermoelectric generators function like heat engines, but are less bulky and have no moving parts.

Thermoelectric generators have been proposed and used in the waste disposal industry and in automotive engineering where considerable waste heat is generated. Radioisotope thermoelectric generators are used in space craft, using radioisotopes to generate heat, thus allowing energy generation for decades from a single fuel source.

There are a number of relevant prior art disclosures including, for example, the following.

U.S. Pat. No. 4,049,877 to Ford Motor Company (Saillant et al., Sep. 20, 1977) discloses an improved thermoelectric generator using alkali metals within in fluid communication with a solid electrolyte.

U.S. Pat. No. 5,892,656 (Bass, Apr. 6, 1999) discloses a thermoelectric generator system. The thermoelectric generator has at least one hot side heat exchanger and at least one cold side heat exchanger and at least one thermoelectric module with thermoelectric elements installed in an injection molded egg crate. The thermoelectric modules are held in close contact with the hot side heat exchanger and the cold side heat sink with a spring force.

U.S. Pat. No. 8,286,424 discloses a thermoelectric generator and an exhaust gas system operatively connected to the thermoelectric generator to heat a portion of the thermoelectric generator with exhaust gas flow through the thermoelectric generator. A coolant system is operatively connected to the thermoelectric generator to cool another portion of the thermoelectric generator with coolant flow through the thermoelectric generator. At least one valve is controllable to cause the coolant flow through the thermoelectric generator in a direction that opposes a direction of the exhaust gas flow under a first set of operating conditions and to cause the coolant flow through the thermoelectric generator in the direction of exhaust gas flow under a second set of operating conditions.

US application 20050000559A1 discloses a thermoelectric generator (e.g., a waste heat recovery apparatus) comprises a heat absorption member made of touch pitch copper and a thermoelectric module in which a plurality of thermoelectric elements are arranged to join electrodes between a pair of insulating substrates, thus utilizing waste heat emitted from a lamp having an exterior wall. One surface of the heat absorption member is formed to match the exterior wall of the lamp, and the other surface is formed to match the thermoelectric module, which is accompanied with a heat dissipating fin, which is further cooled by a cooling fan. At least a part of the heat absorption member can be arranged close to a light emitting tube of the lamp. The thermoelectric module generates electricity based on the heat transferred thereto from the lamp via the heat absorption member.

U.S. Pat. No. 9,881,709 discloses a method for generating electricity on demand from a neutron-activated fuel sample for use in space craft.

### BRIEF DESCRIPTION OF THE INVENTION

Once the capital cost is discounted, this invention can provide unlimited amounts of essentially “free” electricity using a and maintenance-free system.

The present invention relates to a device and system for energy generation comprising (1) a thermoelectric generator (TEG), (2) low-power solid-state heating element, for example an electrically-conductive element that heats up as electric current passes through it, such as a low-power heated graphite element (note that when the word “graphite” is used, it also explicitly implies any carbon-based conductor substance such as, particularly, graphine or carbon nanotubes or carbon nano-materials of any formulation or construction), and (3) a coolant element or heat sink, often employing a liquid coolant conducted through a means of conduction (pipes, tubes, plates or other suitable means).

In this disclosure, we will refer to the heating element as a graphite element, but in various embodiments the heating element may be in the form of another form of carbon or may be another heating element such as a metal element or other electrically conductive substance.

The present invention does not employ an exogenous fuel source, but uses a graphite element to produce heat. Graphite can obtain very high temperatures (up to 1000° C.) with only 3-4 Watts of power input without melting or burning.

The invention (sometimes referred to as a “GTBox”) is a device and system for generating electrical energy. Electrical energy is generated by placing a thermoelectric generator (TEG) element in a temperature gradient. The TEG is placed between a heated graphite element and a cooling element. The graphite element in the GTBox is heated using a low current (as little as 3-4 Watts) which is passed through the graphite element. Heat is converted to electricity by means of a thermoelectric generator (TE) element via the Seebek thermoelectric effect.

It should be noted that one novel element claimed is the combination of the TEG and the graphite heating element, which has the advantage of achieving high temperatures with very low power input.

### BRIEF DESCRIPTION OF THE DRAWINGS

FIG. 1 is a schematic of a simplified “GTBox” system showing the fundamental elements 1=coolant element; 2=thermoelectric element; 3=carbon (graphite/graphene) heating element; 4=arrow representing power input to heat carbon element; 5=electricity output.

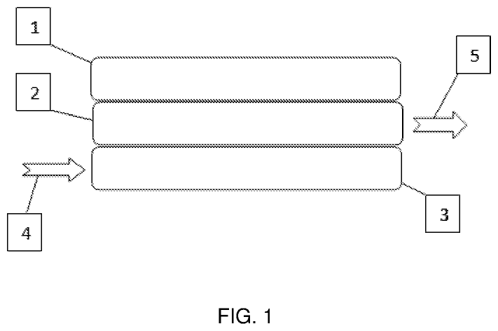

FIG. 2 is a schematic of a “GTBox” which is a thermoelectric generating system. In this figure, the invention employs a number of repeating units (heating units, TEG units and cooling units) placed in combination, however the invention may be practiced using only a single unit comprising a single heating unit, TEG unit and cooling unit. A ‘thermoelectric panel’ (12, 14, 16, 18, 20, 22), sandwiched between a ‘graphite (heating) panel’ (13, 17, 21), and a ‘liquid flowing nitrogen’ (coolant) layer (10, 15, 19, 23), with coolant flowing from one coolant layer to another via insulated conductors/tubes (7, 9, 11, 20). The graphite panel is heated electrically. In this image, the graphite panel is heated using a battery, e.g., a so-called “carbon-algae battery” (6) that enters via terminals (24); but in this disclosure, no enabling description is provided for this “carbon-algae battery” and it should be assumed that electrical energy can be provide by any AC or DC source such as a battery, mains power or any other source of electricity suitable to heat the graphite panel.

### DETAILED DESCRIPTION

The presently disclosed subject matter now will be described more fully hereinafter with reference to the accompanying drawings in which one embodiment is shown. However, it should be understood that this invention may take many different forms and thus should not be construed as being limited to the embodiment set forth herein. All publications mentioned herein are incorporated by reference for all purposes to the extent allowable by law. In addition, in the figures, identical numbers refer to like elements throughout. Additionally, the terms “a” and “an” as used herein do not denote a limitation of quantity, but rather denote the presence of at least one of the referenced items.

The invention encompasses a device (“GT-box”) for generating electrical energy. The “GT-box” is a thermoelectric generating system comprising a graphite heating element, and a thermo-electric generating (TEG) element, and a cooling element. The TEG is placed between a heated graphite element and a cooling element. Graphite is used in the GE-box because it has a very high thermal conductivity, a very high melting point (>150° C.), and a very high electrical resistance. These properties allow pure graphite to obtain very high temperatures (up to 1000° C.) with only 3-4 Watts of power input without melting or burning. This provides a continuous source of heat that will be used to produce a heat gradient across two sides of the TEG to thereby produce an EMF, and thereby, a voltage, and so a current. The coolant (which may be liquid nitrogen, at about −87° C.) and the heated graphite will produce a large temperature differential, and by the Seebek thermoelectric effect, will therefore produce EMF to create a current in a conductor.

The graphite heating element in the GTBox is heated using a low current which is passed through the graphite element. Heat is converted to electricity by means of a thermoelectric generator (TE) element via the Seebek thermoelectric effect.

The graphite (or other) heating element may be heated by other means such as by LASER light, directed onto the graphite/graphene element. In other embodiments, concentrated light such as no-coherent, non-LASER light may be directed onto the graphite, for example using a magnifying lens (or any kind of lens such as a glass lens, a dish, or any other type of lens that can be used to focus and concentrate light) to produce heat.

In other embodiments, LASER or non-LASER light may be shone onto or concentrated onto a heating element that is made of a non-graphite or non-carbon material, such as a metal or other heat-conducting material. Indeed, such light may impinge directly upon a surface of the TEG element.

In other embodiments, radioactive emissions may be used to heat the heating element.

In other embodiments, flame or heated gas or superheated liquids may be used to heat the heating element.

In one embodiment, the graphite element may pure graphite or may be in the form of another form of carbon.

In alternative embodiments, the graphite element may be replaced with another heating element such as a metal element, a metal alloy, or other electrically conductive substance.

The cooling element may comprise a liquid coolant and a means of conducting a liquid. The coolant may be, for example, water, liquid nitrogen or liquid helium or liquid sodium. The means of conduction may be tubes, pipes, flat plates of any other suitable means to contain a liquid.

Pumps may be employed to move the liquid through the pipes. Any of the six basic types of liquid cooling systems may be employed, such as Liquid-to-liquid, Closed-loop dry system, Closed-loop dry system with trim cooling, Open-loop evaporative system, Closed-loop evaporative system, and Chilled water system. Alternatively, any other system may be employed. Other forms of cooling may employ solid heat sink components (usually metal), with or without liquid flow-through components.

### Examples of Embodiments of the Invention

The “GT-box” is a thermoelectric generating system comprising a graphite heating element, a cooling element and a thermo-electric generating (TEG) element. Graphite is used in the GE-box because it has a very high thermal conductivity, a very high melting point (greater than 150° C.), and a very high electrical resistance. These properties allow pure graphite to obtain very high temperatures (up to or greater than 1000° C.) with only 3-4 wats of power input without melting or burning. This provides a continuous source of heat that can be converted into electricity through the TEG modules. The coolant (may be liquid nitrogen, at about −87° C.) and the heated graphite will produce a large temperature differential across the TEG, and by the Seebek thermoelectric effect, will therefore produce EMF to create a current in a conductor.

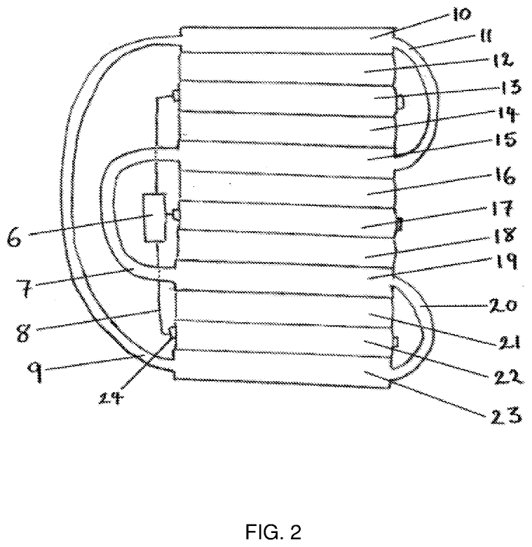

Although the figure (FIG. 2) herein is a schematic of the GT-box shown in an embodiment comprising multiple repeating components—repeated layers of a thermoelectric module disposed between a liquid nitrogen coolant layer and a heated graphite panel, the GT-box may be presented in a much simpler form having only one of each element. The graphite element may be in the form of rods, bars, plates or strands, or any other suitable form. In 2 FIG. 2 the “GTBox” comprises a number of repeating units (heating units, TEG units and cooling units) placed in combination, however the invention may be practiced using only a single unit comprising a single heating unit, TEG unit and cooling unit. A ‘thermoelectric panel’ (12, 14, 16, 18, 20, 22), sandwiched between a ‘graphite (heating) panel’ (13, 17, 21), and a ‘liquid flowing nitrogen’ (coolant) layer (10, 15, 19, 23), with coolant flowing from one coolant layer to another via insulated conductors/tubes (7, 9, 11, 20).

The heating elements are made of pure graphite or graphene. Which has a very high thermal conductivity and very high melting point or greater than 150 Centigrade, and has a very high electrical conductivity. Graphite conducts electricity because it possesses delocalized electrons in its structure. The honeycomb layout of the stacked carbon atoms of graphite leaves a single electron unbound in each hexagon. Each of these electrons is free to move within the structure, enabling electrical conduction. A very small graphite element may be heated to over 1000 degrees Centigrade with only 3-4 Watts of energy input. The coolant used is liquid nitrogen at −87 degrees centigrade. The temperature difference (Δ). This provides a continuous source of heat that will be converted into electricity via the TEG modules.

The graphite panel is heated electrically and it should be assumed that electrical energy can be provide by any AC or DC source such as a battery, mains power or any other source of electricity suitable to heat the graphite panel.

A heating element may be heated directly by passing a current through it or by external heating, electrical heating coils, flame, gas or liquid heating.

The “GT-box” in its simplest form comprises a three-part electrical generator system comprising (1) a thermal electric generator sandwiched between two elements which provide a large temperature differential, and one element of which is carbon which is heated electronically.

In its broadest form the GT-box encompasses the following:

A device for generating electrical energy comprising:
A thermal electric generator (TEG) element having a first surface and a second surface,
A low-power solid-state heating element in contact with one surface, and
A cooling element in contact with the other surface,
A means for conducting electrical power to the solid-state heating element, thereby causing the solid-state heating element to heat up,

And a means for conducting away electrical energy generated by the TEG.

Narrower embodiments encompass the following:

A device for generating electrical energy comprising:
A thermal electric generator (TEG) element having a first surface and a second surface,
A low-power solid-state heating element, which comprises carbon, in contact with one surface, and
A cooling element, which comprises a liquid cooling system of conducting elements through which cooling liquid is made to flow, in contact with the other surface,
A means for heating the solid-state heating element,
And a means for conducting away electrical energy generated by the TEG, the means comprising metal conductors.

Still other narrower embodiments encompass the following:

A device for generating electrical energy comprising:
A thermal electric generator (TEG) element having a first surface and a second surface,

A low-power solid-state heating element, which comprises graphine, in contact with one surface, and

A cooling element, which comprises a liquid nitrogen cooling system in contact with the other surface,

A means for conducting electrical power to the solid-state heating element, the means comprising metal conductors, thereby causing the solid-state heating element to heat up,

And a means for conducting away electrical energy generated by the TEG, the means comprising metal conductors.

In other embodiments, the invention encompasses:

A device for generating electrical energy comprising:
a thermoelectric generator (TEG) element having a first surface and a second surface,
a solid-state heating element comprising a carbon compound, in contact with the first surface, and
a cooling means in contact with the second surface,
a means for heating the solid-state heating element in functional contact with the solid-state heating element,
and a means, connected to the thermal electric generator (TEG) element, for conducting away electrical energy generated by the thermal electric generator element.

In the above embodiments, the solid-state heating element may be composed of a compound that is at least 99% carbon, or 95% carbon, or 90% carbon, or 75% carbon or, 65% carbon, or 50% carbon and may be, for example, made of graphene, graphite, carbon composites, a carbon lattice, diamond or carbon nanotubes.

In other various embodiments, the device of the invention encompasses the following alternative components and methods.

The heating element may be any highly heat-stable, thermally conducting composition such as pure graphite, graphite with traces of other elements, a graphite composite, graphine, another semi-metal, or a metal such as Titanium, Platinum, Tungsten, Palladium, Nickel, Rhodium, Niobium, Tantalum, Iridium etc. Another highly desirable material is Graphene which as the highest thermal conductivity or any substance and is a planar material which conducts at 5300 W/(m·K). Carbon nanotubes or carbon nano-materials of any formulation or construction may be used and are highly conductive and stable. Other materials suitable for the heating element include Carbon Nanotubes, an axial material that conducts at 3000-3500 W/(m·K); Synthetic Diamond, an isotropic material that conducts at 2320 W/(m·K); Annealed Pyrolytic Graphite, a planar material, that conducts at 1700 W/(m·K); Natural diamond (isotropic) that conducts at approximately 900 W/(m·K). Other highly thermally conductive materials include silver, copper, aluminum, brass and steel. Stainless steels are generally only about a third as thermally conductive as carbon steel. Copper is about ten times as thermally conductive as carbon steel.

The cooling element may comprise any cooling gas or liquid which can be made to flow through conducting pipes, tubes, plates or other suitable means. It may be a liquid such as water, liquid nitrogen, liquid helium or liquid sodium, oil etc. or it could be in the form of a sublimating solid such as carbon dioxide. The means of conduction may be tubes, pipes, flat plates of any other suitable means to contain a liquid.

Any type of liquid cooling system may be employed, such as Liquid-to-liquid, Closed-loop dry system, Closed-loop dry system with trim cooling, Open-loop evaporative system, Closed-loop evaporative system, and Chilled water system. Alternatively, any other system may be employed. Other forms of cooling may employ solid heat sink components (usually metal), with or without liquid flow-through components.

The graphite/graphene (or other) heating element may be heated by passing a current through the element, or by flame, heated gas or heated liquid or by LASER. Graphite and graphine can obtain very high temperatures (up to 1000° C.) with only 3-4 Watts of power input without melting or burning.

A graphite/graphene heating element may be heated by passing an electric current through it with an energy input of, for example, 0.1-10 watts, 0.5-30 watts, 1-25 watts, 1-20 watts, 2-20 watts, 3-15 watts, 2-10 watts, 2-5 watts, or 1-3 watts. The wattage may be <100 watts, <50, <25, <12, <7, <5 or <watts.

The electric current may be supplied by mains current or by a battery. In one embodiment, a new battery system is used called a “carbon-algae battery” which is not described or enabled in this disclosure.

Alternatively, the graphite/graphene (or other) heating element may be heated by other means such as by LASER light, directed onto the graphite element, or by concentrated light such as no-coherent, non-LASER light that may be directed onto the graphite, for example using a magnifying lens or any kind of lens, a dish etcetera that can be used to focus and concentrate light.

In other embodiments, LASER or non-LASER light may be concentrated onto a heating element that is made of a non-graphite or non-carbon material, such as a metal or other heat-conducting material. Indeed, such light may impinge directly upon a surface of the TEG element.

For embodiments where the heating element is heated by light, particularly by LASER light, the light source may be remote from the heating element of the device. As long as there is line-of-sight visual contact, the device can be energized and heated from afar, e.g., from meters, kilometers, or even hundreds or thousands of kilometers away. One embodiment relates to powering of drones, aircraft or orbiting space vehicles. In one relevant example, US Army's Communications-Electronics Research, Development and Engineering Center based in Maryland are developing a power beaming system with a combination of lasers and efficient photovoltaic cells with the aim of powering a flying drone indefinitely from the ground, patrolling indefinitely above a base or fly over a convoy for its entire route. The system works by firing laser light at the drone's photovoltaic cell, which then converts the light into electricity. The present invention provides a highly efficient, stable and hardy system for such remote power beaming systems. The TEG may be powered from the ground by a beam of LASER light, which tracks the drone or aircraft using a GPS-controlled positioning system. The power of the LASER light required may be less than that required by the present PV system, thereby alleviating the present problems with overheating the drone in flight.

In other embodiments, radioactive emissions may be used to heat the heating element. Such embodiments would be useful for systems where electricity production is needed in a maintenance-free system for many years, such as in space-craft.

Once the capital cost is discounted, this invention can provide unlimited amounts of essentially “free” electricity using a and maintenance-free system.

### Definitions and Further Information Relevant to Embodiments

Cooling means=any system used to cool. The cooling element may comprise a radiator, heat sink or a liquid coolant and a means of conducting a liquid. The coolant may be, for example, water, liquid nitrogen or liquid helium or liquid sodium. The means of conduction may be tubes, pipes, flat plates of any other suitable means to contain a liquid.

“means for heating the solid-state heating element”=any device or system used to heat the heating element, such as an electric current run through the heating element, a flame, a LASER, heated liquids or gasses of concentrated light.

“a means for conducting away electrical energy generated by the thermo-electric (or thermal-electric) generator element”=any device or system used to channel electrical current from the thermo-electric generator, such as a simple electrical circuit made from conductors.

Heating element=any device or substance that in this invention is heated to provide the hotter part of the heating-cooling pair, and it may be made from any suitable substance such as carbon, graphite, graphene, carbon nanotubes or a matter such as copper, aluminum, titanium, or any other metal.

Coolant=a substance used as the colder part of the heating-cooling couple, such as coolant selected from the group consisting of water, liquid nitrogen, liquid helium, liquid sodium and oil.

Thermoelectric generator=A thermoelectric generator (TEG), also called a Seebeck generator, is a solid state device that converts heat flux (temperature differences) directly into electrical energy through a phenomenon called the Seebeck effect (a form of thermoelectric effect). Thermoelectric generators function like heat engines, but are less bulky and have no moving parts. Thermoelectric generators are used in power plants in order to convert waste heat into additional electrical power and in automobiles as automotive thermoelectric generators (ATGs) to increase fuel efficiency. Another application is radioisotope thermoelectric generators which are used in space probes, which has the same mechanism but use radioisotopes to generate the required heat difference.

A thermoelectric module is a circuit containing thermoelectric materials which generates electricity from heat directly. A thermoelectric module consists of two dissimilar thermoelectric materials joined at their ends: an n-type (negatively charged), and a p-type (positively charged) semiconductor. A direct electric current will flow in the circuit when there is a temperature difference between the ends of the materials. Generally, the current magnitude is directly proportional to the temperature difference. In application, thermoelectric modules in power generation work in very tough mechanical and thermal conditions. Because they operate in a very high temperature gradient, the modules are subject to large thermally induced stresses and strains for long periods of time. They also are subject to mechanical fatigue caused by large number of thermal cycles.

Thus, the junctions and materials must be selected so that they survive these tough mechanical and thermal conditions. Also, the module must be designed such that the two thermoelectric materials are thermally in parallel, but electrically in series. The efficiency of a thermoelectric module is greatly affected by the geometry of its design. Using thermoelectric modules, a thermoelectric system generates power by taking in heat from a source such as a hot exhaust flue. In order to do that, the system needs a large temperature gradient, which is not easy in real-world applications. The cold side must be cooled by air or water. Heat exchangers are used on both sides of the modules to supply this heating and cooling. There are many challenges in designing a reliable TEG system that operates at high temperatures. Achieving high efficiency in the system requires extensive engineering design in order to balance between the heat flow through the modules and maximizing the temperature gradient across them. To do this, designing heat exchanger technologies in the system is one of the most important aspects of TEG engineering. In addition, the system requires to minimize the thermal losses due to the interfaces between materials at several places. Another challenging constraint is avoiding large pressure drops between the heating and cooling sources. After the DC power from the TE modules passes through an inverter, the TEG produces AC power, which in turn, requires an integrated power electronics system to deliver it to the customer. Only a few known materials to date are identified as thermoelectric materials. Most thermoelectric materials today have a zT, the figure of merit, value of around 1, such as in Bismuth Telluride (Bi2Te3) at room temperature and lead telluride (PbTe) at 500-700K. However, in order to be competitive with other power generation systems, TEG materials should have a zT of 2-3. Most research in thermoelectric materials has focused on increasing the Seebeck coefficient (S) and reducing the thermal conductivity, especially by manipulating the nanostructure of the thermoelectric materials. Because the thermal and electrical conductivity correlate with the charge carriers, new means must be introduced in order to conciliate the contradiction between high electrical conductivity and low thermal conductivity as indicated.

Thermocouples used in the invention may be of any suitable type, for example the following. Nickel-alloy thermocouples (types E, J, K, M, N, T); Platinum/rhodium-alloy thermocouples (types B, R, S); Tungsten/rhenium-alloy thermocouples (types C, D, G); Chromel-gold/iron-alloy thermocouples; Platinum/molybdenum-alloy thermocouples;

Iridium/rhodium alloy thermocouples; Pure noble-metal thermocouples Au—Pt, Pt—Pd; and Skutterudite thermocouples.

Power production by use of a thermocouple. A thermocouple can produce current to drive some processes directly, without the need for extra circuitry and power sources. For example, the power from a thermocouple can activate a valve when a temperature difference arises. The electrical energy generated by a thermocouple is converted from the heat which must be supplied to the hot side to maintain the electric potential. A continuous transfer of heat is necessary because the current flowing through the thermocouple tends to cause the hot side to cool down and the cold side to heat up (the Peltier effect).

Thermopiles. Thermocouples can be connected in series to form a thermopile, where all the hot junctions are exposed to a higher temperature and all the cold junctions to a lower temperature. The output is the sum of the voltages across the individual junctions, giving larger voltage and power output.

Thermocouples have found use in various electricity generating applications such as in radioisotope thermoelectric generators in which the radioactive decay of transuranic elements provides a heat source to power spacecraft on missions too far from the Sun to use solar power. Thermopiles heated by kerosene lamps have been used to run battery-less radio receivers. Lanterns that use the heat from a candle can be used to run light-emitting diodes.

LASER=A laser is a device that emits light through a process of optical amplification based on the stimulated emission of electromagnetic radiation. The term “laser” originated as an acronym for “light amplification by stimulated emission of radiation”.

Heater=any device or system used to heat a component or element of the device.

Further Notes

Note that when the terms “first surface” and “second surface” are used, these terms are merely to differentiate one surface from another and are not meant to functionally define the surfaces, so that a claim element may be in contact with either surface, and “first” and “second” can be used interchangeably.

The claims, disclosure and drawings of the present invention define but are not intended to limit the invention.

All patents and publications disclosed herein are incorporated by reference to the fullest extent permissible by law.

1. A device for generating electrical energy comprising:
a plurality of repeating units placed in combination and in physical contact with one another, each unit comprising:
a thermoelectric generator element having a first surface and a second surface,
a solid-state heating element comprising a carbon compound, in contact with the first surface, and a cooling means in contact with the second surface,
a means for heating the solid-state heating element in functional contact with the solid-state heating element,
electrical conductors connected to every thermoelectric generator element, for conducting electrical energy generated by the thermoelectric generator element;
wherein the solid-state heating element comprises carbon nanotubes;
wherein the means for heating the carbon nanotubes comprises a beam of LASER light directed onto the carbon nanotubes.

2. The device of claim 1 wherein every thermoelectric generator element comprises a thermocouple.

3. The device of claim 2 wherein the thermocouple is a Nickel-alloy thermocouple.

4. The device of claim 2 wherein the thermocouple is a Platinum/rhodium-alloy thermocouple.

5. The device of claim 2 wherein the thermocouple is a Tungsten/rhenium-alloy thermocouple.

6. The device of claim 2 the thermocouple is a Platinum/molybdenum-alloy thermocouple.

7. The device of clam 1 wherein, the power provided to the carbon nanotubes is not more than 12 Watts.

8. The device of clam 7 wherein the power provided to the carbon nanotubes is not more than 5 Watts.

9-12. (canceled)

13. The device of claim 1 wherein the cooling means comprises a liquid coolant.

14. The device of claim 13 wherein the liquid coolant is liquid nitrogen.

15. The device of claim 13 wherein the cooling means comprises a system of pipes, tubes or plates adapted to contain and convey a liquid coolant.

16. (canceled)

17. A method for producing electrical energy, the method comprising
(a) providing: a device for generating electrical energy comprising:
a thermoelectric generator element having a first surface and a second surface,
a solid-state heating element comprising a carbon compound, in contact with the first surface, and
a cooling means in contact with the second surface,
a means for heating the solid-state heating element in functional contact with the solid-state heating element,
and a means, connected to the thermoelectric generator element, for conducting away electrical energy generated by the thermoelectric generator element;
(b) heating the heating element thereby creating a thermal gradient across the thermoelectric generator, thereby creating an electromotive force;
(c) providing a circuit in contact with the thermoelectric generator so that the electromotive force creates an electric current in the circuit;
(d) collecting or using the electrical current so produced.

18. The method of claim 17 wherein the solid-state heating element comprises graphite of graphene.

19. The method of claim 18 wherein the graphite of graphene is heated by the passage of an electrical current through it.

20. The method of claim 18 wherein the graphite of graphene is heated by means of light energy imprinting upon it.
